(19) United States
(12) Patent Application Publication
(10) Pub. No.: US 2025/0287590 A1
(43) Pub. Date: Sep. 11, 2025

(54) SEMICONDUCTOR DEVICE AND METHOD OF MANUFACTURING THE SAME

(71) Applicant: Kioxia Corporation, Tokyo (JP)

(72) Inventors: Hiroki KITAYAMA, Yokkaichi (JP); Toshiyuki MORITA, Yokkaichi (JP)

(73) Assignee: Kioxia Corporation, Tokyo (JP)

(21) Appl. No.: 18/816,279

(22) Filed: Aug. 27, 2024

(30) Foreign Application Priority Data
Mar. 7, 2024 (JP) 2024-035254

(51) Int. Cl. H10B 43/27

(52) U.S. Cl. CPC H10B 43/27

(57) ABSTRACT

In one embodiment, a method of manufacturing a semiconductor device includes forming a first insulator. The method further includes forming a first layer including tungsten and nitrogen, on the first insulator. The method further includes reducing nitrogen concentration in the first layer by annealing the first layer in a state that the first layer is exposed. The method further includes forming a second layer including tungsten, on the first layer after the annealing.

### CROSS REFERENCE TO RELATED APPLICATION

This application is based upon and claims the benefit of priority from the prior Japanese Patent Application No. 2024-035254, filed on Mar. 7, 2024, the entire contents of which are incorporated herein by reference.

### FIELD

Embodiments described herein relate to a semiconductor device and a method of manufacturing the same.

### BACKGROUND

Regarding a semiconductor device including an interconnect layer such as an electrode layer, it is desired to reduce the electric resistance of the interconnect layer and suppress diffusion of atoms from the interconnect layer to another layer.

### BRIEF DESCRIPTION OF THE DRAWINGS

FIG. 1 is a perspective view showing a structure of a semiconductor device of a first embodiment;

FIGS. 2 to 5 are sectional views showing a method of manufacturing the semiconductor device of the first embodiment;

FIGS. 6A and 6B are sectional views showing a structure of a semiconductor device of a comparative example of the first embodiment;

FIG. 7 is a sectional view showing the structure of the semiconductor device of the first embodiment;

FIGS. 8A to 8C are sectional views showing details of the method of manufacturing the semiconductor device of the first embodiment;

FIGS. 9A and 9B are graphs concerning characteristics of the semiconductor device of the first embodiment;

FIG. 10 is another graph concerning characteristics of the semiconductor device of the first embodiment;

FIG. 11 is a sectional view showing a structure of a semiconductor device of a variation of the first embodiment;

FIGS. 12A and 12B are sectional views showing a structure of a semiconductor device of a second embodiment, and a structure of a semiconductor device of a variation of the second embodiment;

FIGS. 13A to 13D are sectional views showing a method of manufacturing the semiconductor device of the second embodiment;

FIG. 14 is a sectional view showing a structure of a semiconductor device of a third embodiment;

FIG. 15 is a sectional view showing a structure of a columnar portion of the third embodiment; and

FIGS. 16 and 17 are sectional views showing a method of manufacturing the semiconductor device of the third embodiment.

### DETAILED DESCRIPTION

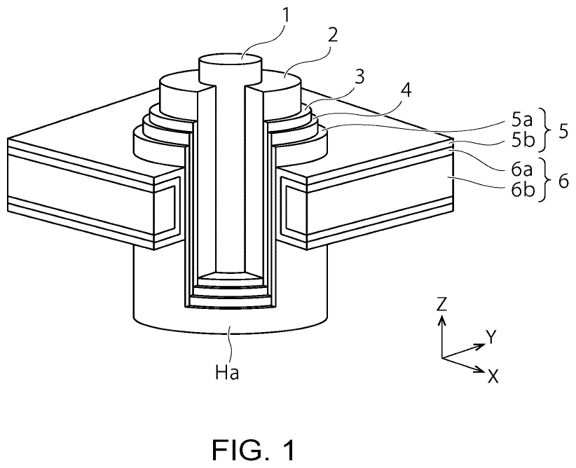

Embodiments will now be explained with reference to the accompanying drawings. In FIGS. 1 to 17, the same components are denoted by the same reference signs, and redundant description thereof will be omitted.

In one embodiment, a method of manufacturing a semiconductor device includes forming a first insulator. The method further includes forming a first layer including tungsten and nitrogen, on the first insulator. The method further includes reducing nitrogen concentration in the first layer by annealing the first layer in a state that the first layer is exposed. The method further includes forming a second layer including tungsten, on the first layer after the annealing.

### First Embodiment

FIG. 1 is a perspective view showing a structure of a semiconductor device of a first embodiment. The semiconductor device of the present embodiment includes, for example, a three-dimensional semiconductor memory.

The semiconductor device of the present embodiment includes a core insulator 1, a channel semiconductor layer 2, a tunnel insulator 3, a charge storage layer 4, a block insulator 5, and an electrode layer 6. The block insulator 5 includes an insulator 5a and an insulator 5b. The electrode layer 6 includes a barrier metal layer 6a and an electrode material layer 6b. The electrode layer 6 is an example of the first interconnect layer. The barrier metal layer 6a is an example of a first layer. The electrode material layer 6b is an example of second and third layers and an example of an interconnect material layer in the first interconnect layer.

In FIG. 1, a plurality of electrode layers and a plurality of insulators are stacked alternately on a substrate, and a memory hole Ha is provided in the electrode layers and the insulators. FIG. 1 shows one electrode layer 6 of the electrode layers. The electrode layers function, for example, as word lines for a three-dimensional semiconductor memory. FIG. 1 shows an X direction and a Y direction parallel to a surface of the substrate and perpendicular to each other, and a Z direction perpendicular to the surface of the substrate. In the present specification, a +Z direction is treated as an upward direction and a −Z direction is treated as a downward direction. The −Z direction may or may not coincide with the gravity direction.

The core insulator 1, the channel semiconductor layer 2, the tunnel insulator 3, the charge storage layer 4, and the insulator 5a are formed in the memory hole Ha, making up a memory cell of the three-dimensional semiconductor memory. The insulator 5a is formed on side faces of the electrode layers and insulators in the memory hole Ha, and the charge storage layer 4 is formed on a side face of the insulator 5a. The charge storage layer 4 can store signal charges of the three-dimensional semiconductor memory. The tunnel insulator 3 is formed on a side face of the charge storage layer 4, and the channel semiconductor layer 2 is formed on a side face of the tunnel insulator 3. The channel semiconductor layer 2 functions as a channel of the three-dimensional semiconductor memory. The core insulator 1 is formed on a side face of the channel semiconductor layer 2. The insulator 5a is an example of a third insulator. The tunnel insulator 3 is an example of a fourth insulator.

The insulator 5a is, for example, a SiO₂ film (silicon oxide film). The charge storage layer 4 is, for example, a SiN film (silicon nitride film). The tunnel insulator 3 is, for example, a SiO₂ film. The channel semiconductor layer 2 is, for example, a polysilicon layer. The core insulator 1 is, for example, a SiO₂ film.

The insulator 5b, the barrier metal layer 6a, and the electrode material layer 6b are formed between two of the plurality of insulators, i.e., formed on a lower face of the upper insulator, an upper face of the lower insulator, and the side face of the insulator 5a in sequence. The plurality of insulators and the block insulator 5 are examples of the first insulator. The plurality of insulators are also examples of a second insulator.

The insulator 5b is, for example, Al₂O₃ film (aluminum oxide film). The barrier metal layer 6a is, for example, a W (tungsten) layer including N (nitrogen) atoms as impurity atoms. The electrode material layer 6b is, for example, a W (tungsten) layer. Further details on the barrier metal layer 6a and the electrode material layer 6b will be described later.

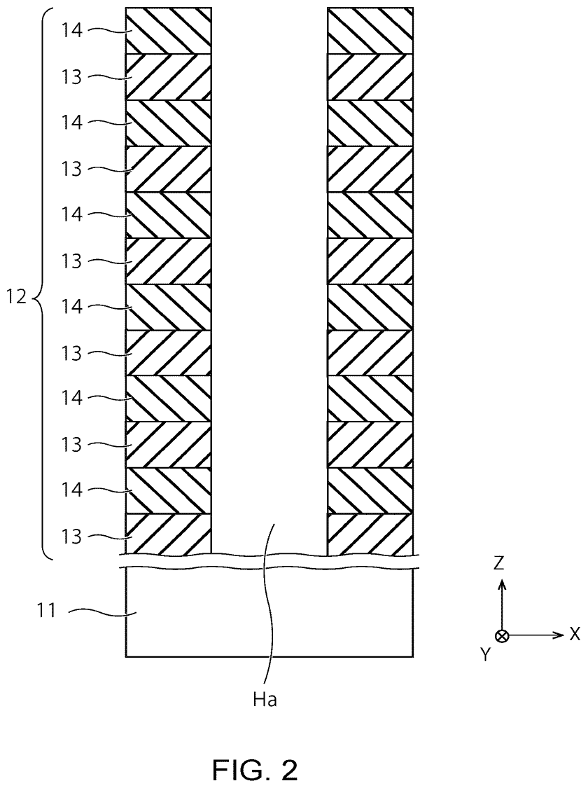

FIGS. 2 to 5 are sectional views showing a method of manufacturing the semiconductor device of the first embodiment.

First, a substrate 11 is prepared, and a stacked film 12 including a plurality of sacrificial layers 13 and a plurality of insulators 14 alternately is formed on the substrate 11 (FIG. 2). The stacked film 12 is formed by stacking the plurality of sacrificial layers 13 and the plurality of insulators 14 alternately on the substrate 11. The stacked film 12 may be formed either directly on the substrate 11 or formed on the substrate 11 via another layer. The substrate 11 is, for example, a semiconductor substrate such as a Si (silicon) substrate. The sacrificial layers 13 are, for example, SiN films. The insulators 14 are, for example, SiO₂ films. The sacrificial layers 13 are an example of a fourth layer. The insulators 14 are examples of first and second insulators.

Next, a plurality of memory holes Ha are formed in the stacked film 12 by photolithography and RIE (reactive ion etching) (FIG. 2). FIG. 2 shows one of the memory holes Ha. Each of the memory holes Ha of the present embodiment has a circular shape in planar view and penetrates the stacked film 12.

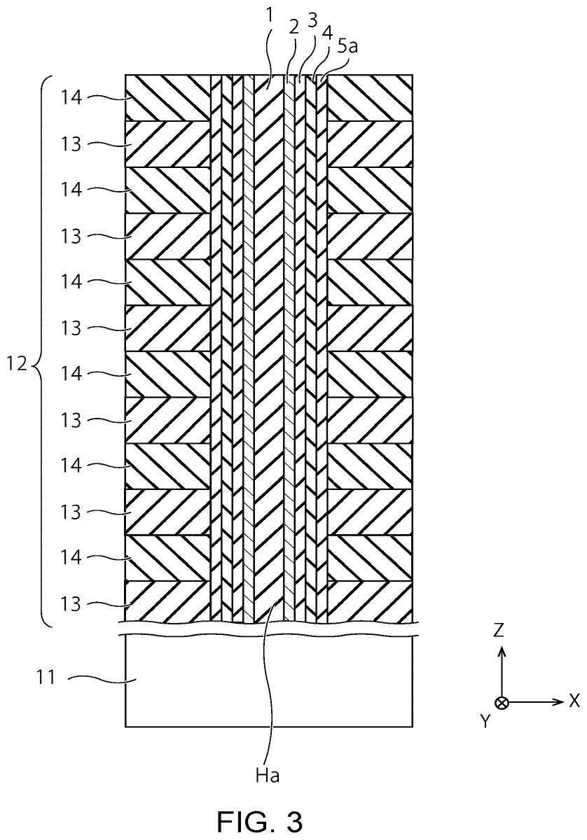

Next, the insulator 5a, the charge storage layer 4, the tunnel insulator 3, the channel semiconductor layer 2, and the core insulator 1, are formed in sequence on a side face of the stacked film 12 in each of the memory holes Ha (FIG. 3). The insulator 5a, the charge storage layer 4, the tunnel insulator 3, and the channel semiconductor layer 2 are formed to have a tubular shape extending in the Z direction. The core insulator 1 is formed to have a columnar shape extending in the Z direction.

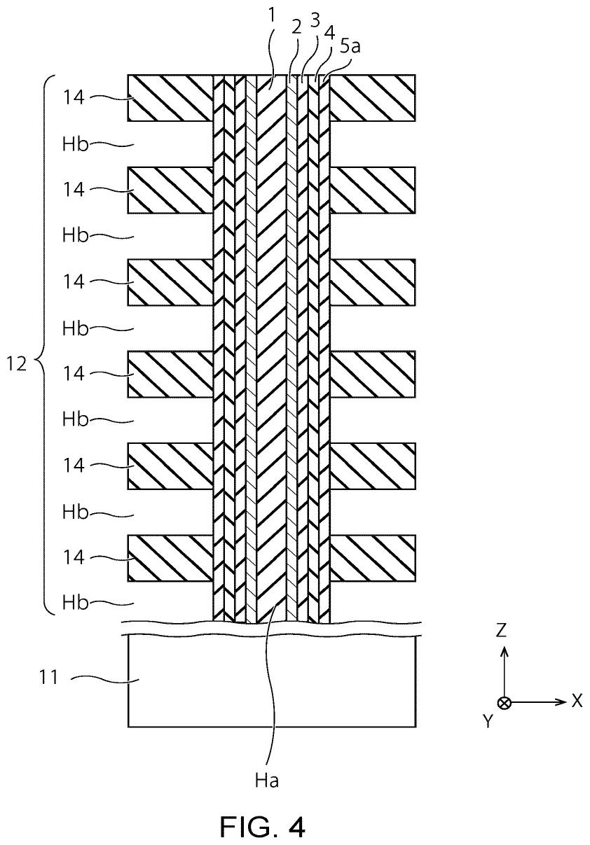

Next, a plurality of slits are formed in the stacked film 12 (not 10 shown) and the sacrificial layers 13 are removed from the slits using a chemical solution such as a phosphoric acid aqueous solution. As a result, a plurality of concave portions Hb are formed in the stacked film 12 (FIG. 4). The concave portions Hb are an example of first concave portions.

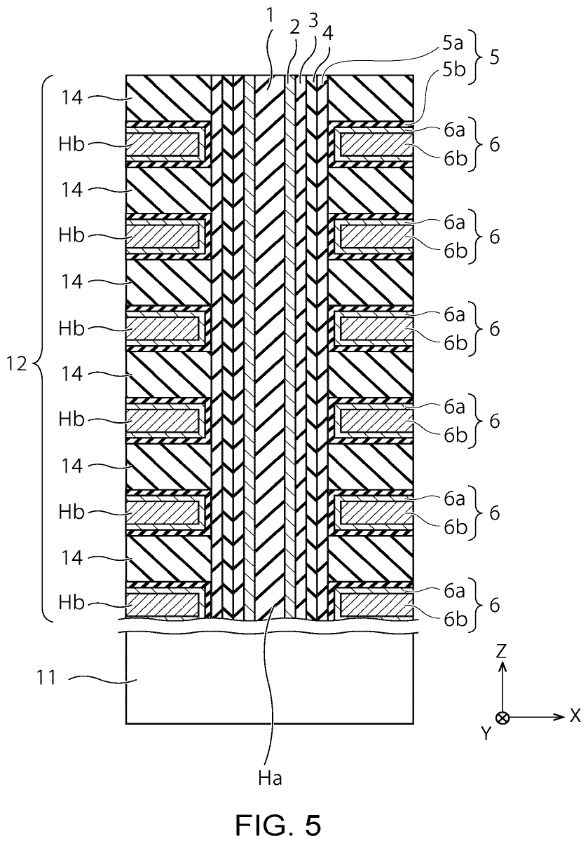

15 Next, the insulator 5b, the barrier metal layer 6a, and the electrode material layer 6b are formed in sequence on surfaces of the insulators 5a and 14 in each of the concave portions Hb (FIG. 5). As a result, the block insulator 5 including the insulators 5a and 5b is formed. Furthermore, the electrode layer 6 including the barrier metal layer 6a and the electrode 20 material layer 6b is formed in each of the concave portions Hb. Furthermore, the stacked film 12 including a plurality of the electrode layers 6 and a plurality of insulators 14 alternately is formed on the substrate 11. In this way, a replacement process is performed to replace the sacrificial layers 13 with the electrode layers 6. The insulators 14 and 25 the block insulators 5 are examples of the first insulator.

Each of the concave portions Hb is formed between a pair of the insulators 14 adjacent to each other in the Z direction. In each of the concave portions Hb, the insulator 5b, the barrier metal layer 6a, and the electrode material layer 6b are formed on the lower face of the upper insulator 14, the upper face of the lower insulator 14, and the side face of the insulator 5a in sequence. As a result, each of the electrode layers 6 is formed between the insulators 14 via the insulator 5b. On the other hand, after the replacement process, in each of the memory holes Ha, the charge storage layer 4 is formed on a side face of the plurality of electrode layers 6 via the insulator 5a and the channel semiconductor layer 2 is provided on the side face of the charge storage layer 4 via the tunnel insulator 3.

In this way, the semiconductor device of the present embodiment is manufactured (FIG. 5). FIG. 1 shows part of the semiconductor device shown in FIG. 5.

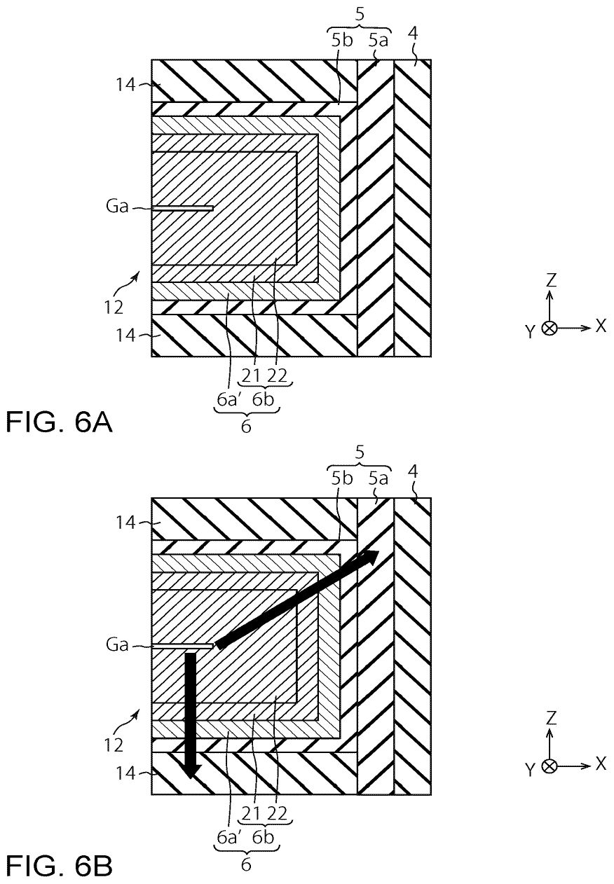

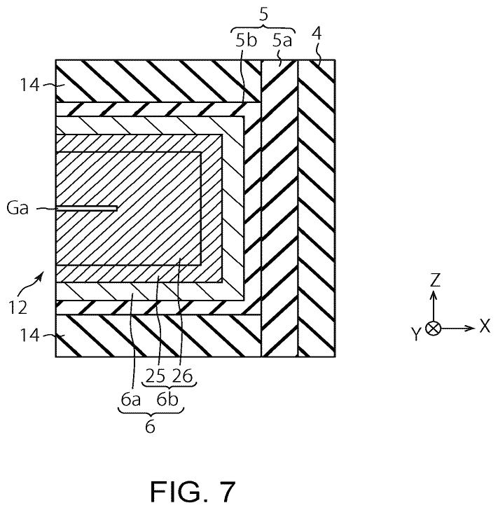

Next, the first embodiment will be compared with a comparative example with reference to FIGS. 6A, 6B, and 7.

FIGS. 6A and 6B are sectional views showing a structure of a semiconductor device of a comparative example of the first embodiment.

FIG. 6A shows the structure of the semiconductor device of the present comparative example. As with FIG. 5, FIG. 6A shows the charge storage layer 4, the block insulator 5, the electrode layer 6, the insulators 14, and the like. However, the electrode layer 6 of the present comparative example includes a barrier metal layer 6a′ instead of the barrier metal layer 6a. FIG. 6A further shows a seam Ga formed in the electrode material layer 6b during formation of the electrode material layer 6b. The seam Ga is an air gap extending generally in parallel to an X-Y plane. As shown in FIG. 6A, the electrode material layer 6b of the present comparative example includes metal layers 21 and 22 formed on a side face, upper face, and lower face of the barrier metal layer 6a′ in sequence.

The barrier metal layer 6a′ is, for example, a TiN film (titanium nitride film). Each of the metal layers 21 and 22 is, for example, a W layer. According to the present comparative example, the barrier metal layer 6a′ and the metal layer 22 are polycrystalline layers and the metal layer 21 is an amorphous layer. Thus, the metal layer 22 is lower in resistivity than the metal layer 21.

According to the present comparative example, the metal layer 21 is formed using WF₆ gas and B₂H₆ gas and the metal layer 22 is formed using WF₆ gas and H₂ gas (where W is tungsten, F is fluorine, B is boron, and H is hydrogen). Thus, the metal layers 21 and 22 include F atoms as impurity atoms.

FIG. 6B is a sectional view for explaining a problem with the semiconductor device of the present comparative example. With the present comparative example, if the electrode layers 6 are reduced in thickness to downsize the semiconductor device, it becomes difficult to embed the electrode material layers 6b in the concave portions Hb (see FIG. 5) and easy for large seams Ga to be formed in the electrode material layers 6b. F-atom concentration in the electrode layers 6 is high on surfaces of the electrode layers 6, and thus F atoms in the electrode layers 6 exist at high concentration on the surfaces of the electrode layers 6 facing the seams Ga. This makes it easy for the F atoms in the electrode layers 6 to diffuse through the seams Ga, which might cause failures (e.g., an electrical insulation failure) of the semiconductor device. Thus, it is desired to inhibit diffusion of F atoms by means of the barrier metal layers 6a′. The arrows shown in FIG. 6B indicate how F atoms diffuse from the electrode layer 6 to other layers (e.g., insulators 14).

FIG. 7 is a sectional view showing the structure of the semiconductor device of the first embodiment.

As shown in FIG. 7, the electrode layer 6 of the present embodiment includes the barrier metal layer 6a. The electrode material layer 6b of the present embodiment includes metal layers 25 and 26 formed in sequence on a side face, upper face, and lower face of the barrier metal layer 6a. The barrier metal layer 6a is an example of the first layer. The metal layer 25 is an example of the third layer. The metal layer 26 is an example of the second layer.

The barrier metal layer 6a of the present embodiment includes W (tungsten) atoms and N (nitrogen) atoms. The barrier metal layer 6a is, for example, a W layer including N atoms as impurity atoms as described above. That is, the barrier metal layer 6a includes, for example, W as a principal component. Note that a W layer including N atoms as impurity atoms is denoted as a W(N) layer. As described later, when a composition ratio of W atoms and N atoms in a WN film is 6:4, a ratio k of the number n2 of N atoms to the sum of the number of W atoms n1 and the number n2 of N atoms in the W (N) layer of the present embodiment is lower than 40% (i.e., k=n2/(n1+n2)<0.40). Besides, a ratio of the number of W atoms to the number of all the atoms in the barrier metal layer 6a of the present embodiment is larger than 60%. According to the present embodiment, the barrier metal layer 6a is a crystalline layer, i.e., for example, a polycrystalline layer.

The metal layer 25 is, for example, a W layer. The metal layer 26 is, for example, a W layer. Each of the metal layers 25 and 26 may or may not include N atoms as impurity atoms. However, N concentration in the barrier metal layer 6a of the present embodiment is higher than N concentration in the metal layer 26 even when the metal layer 26 includes N atoms as impurity atoms. The N concentration in the metal layer 26 is, for example, 7.0×10¹⁹ to 2.0×20²⁰ atoms/cm³. Similarly, N concentration in the barrier metal layer 6a of the present embodiment is higher than N concentration in the metal layer 25 even when the metal layer 25 includes N atoms as impurity atoms. According to the present embodiment, the metal layer 26 is a polycrystalline layer and the metal layer 25 is an amorphous layer. Thus, the metal layer 26 is lower in resistivity than the metal layer 25.

The barrier metal layer 6a is formed, for example, by forming a WN film by CVD and changing the WN film into a W (N) layer by annealing as described later. According to the present embodiment, the WN film is annealed using a predetermined gas such as H₂ (hydrogen) gas (H₂ annealing). The predetermined gas may be, for example, Ar (argon) gas or N₂ (nitrogen) gas. The annealing is performed, for example, at a temperature higher than 40020 C., and desirably at a temperature equal to or higher than 50020 C. According to the present embodiment, the WN film, which is an amorphous layer, is crystalized by the annealing and changes into a W(N) layer (the barrier metal layer 6a), which is a crystalline layer. The annealing is performed, for example, at a temperature higher than 400° C. and lower than 1050° C. Duration of the annealing is, for example, one hour, but another duration may be used. According to the present embodiment, the W(N) layer (barrier metal layer 6a) with a ratio k of less than 40% is formed from the WN film with a ratio k of 40%, and the N concentration in the W(N) layer becomes lower than the N concentration in the WN film. The WN film is an example of the first layer.

The WN film used to form the barrier metal layer 6a is formed using, for example, a source gas including W and a reducing gas including N. The source gas is, for example, WF₆ gas. The reducing gas is, for example, NH₃ (ammonia) gas. In this case, the WN film as well as the W(N) layer (barrier metal layer 6a) formed of the WN film can include F atoms and H atoms as impurity atoms. The source gas may include a halogen other than F, i.e., for example, Cl (chlorine). For example, when a WN film is formed using WOCl₄ gas and NH₃ gas, the WN film and the W(N) layer can include CI atoms, O atoms, and H atoms as impurity atoms (where O denotes oxygen). Note that the WN film used to form the barrier metal layer 6a may be formed by a method other than CVD. For example, the WN film used to form the barrier metal layer 6a may be formed by ALD (atomic layer deposition).

The metal layer 25 is formed using, for example, a source gas including W and F, and a reducing gas including B and H. The source gas is, for example, WF₆ gas. The reducing gas is, for example, B₂H₆. In this case, the metal layer 25 may include F atoms, B atoms, and H atoms as impurity atoms. The source gas may include a halogen other than F, i.e., for example, Cl (chlorine). An example of such a source gas is WOCl₄ gas. In this case, the metal layer 25 may include Cl atoms and O atoms as impurity atoms. On the other hand, the reducing gas may include Si instead of B. Examples of such a reducing gas include SiH₄ gas and Si₂H₆ gas. In this case, the metal layer 25 can include Si atoms and H atoms as impurity atoms.

The metal layer 26 is formed using, for example, a source gas including W and F, and a reducing gas including H. The source gas is, for example, WF₆ gas. The reducing gas is, for example, H₂ gas. In this case, the metal layer 26 can include F atoms and H atoms as impurity atoms. The source gas may include a halogen other than F, i.e., for example, Cl (chlorine). An example of such a source gas is WOCl₄ gas. In this case, the metal layer 26 may include Cl atoms and O atoms as impurity atoms. By forming the electrode layer 6 using the W(N) layer (barrier metal layer 6a), the present embodiment makes it possible to reduce the metal layer 25 in thickness compared to when the barrier metal layer 6a is a TIN film. Thus, by reducing the thickness of the metal layer 25, which is a high-resistance layer, electric resistance of the electrode layer 6 can be reduced. In addition, the W(N) layer is more effective than a WN film in inhibiting the diffusion of F atoms. Thus, by forming the electrode layer 6 using the W N) layer, the present embodiment makes it possible to effectively inhibit diffusion of F atoms. For example, the F (fluorine) concentration in the insulators 14 in the case of using the W(N) layer becomes equal to or lower than one third of the F concentration in the insulators 14 in the case of using no W(N) layer. It is thereby understood that the W(N) layer suppresses the diffusion of the F atoms. This similarly applies to halogen atoms other than F atoms. Further details on this subject will be described later.

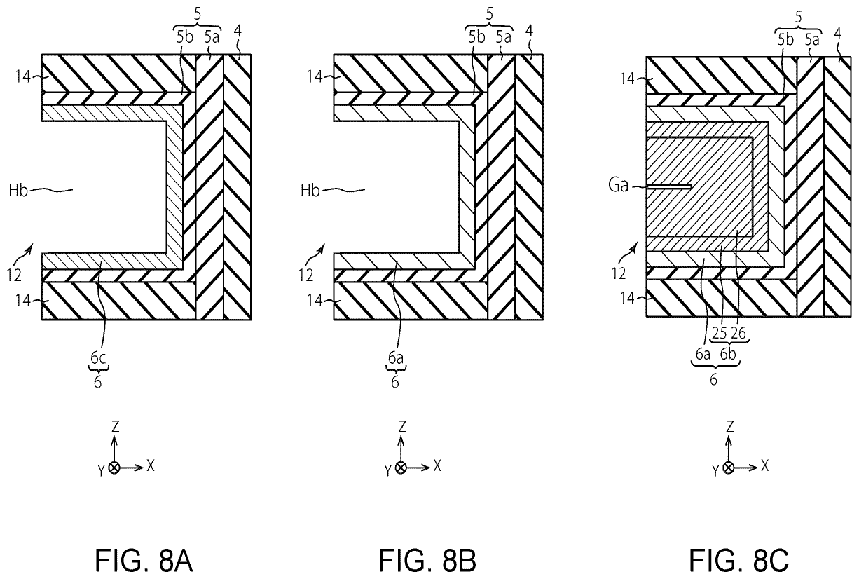

FIGS. 8A to 8C are sectional views showing details of the method of manufacturing the semiconductor device of the first embodiment. More specifically, FIGS. 8A to 8C show the process of forming the structure shown in FIG. 7.

In forming the electrode layer 6 in each concave portion Hb, first, a barrier metal layer 6c is formed on a surface of the insulator 5b (FIG. 8A). The barrier metal layer 6c is, for example, a WN film. The barrier metal layer 6c of the present embodiment is formed by CVD using WF6 gas and NH₃ gas, and a composition ratio of W atoms and N atoms in the barrier metal layer 6c is 6:4. Consequently, the ratio k of the number n2 of N atoms to the sum of the number of W atoms n1 and the number n2 of N atoms in the barrier metal layer 6c is 40% (i.e., k=n2/(n1+n2)=0.40). The barrier metal layer 6c is an example of the first layer.

Next, the barrier metal layer 6c is annealed (FIG. 8B). The annealing is performed, for example, using a predetermined gas (e.g., H₂ gas, Ar gas or H₂ gas) at a temperature higher than 400° C. The annealing is performed at a temperature of, for example, 500° C. or above, but lower than 1050° C. As a result, the barrier metal layer 6c changes into the barrier metal layer 6a. The barrier metal layer 6a is, for example, a W(N) layer, i.e., a W layer including N atoms as impurity atoms. According to the present embodiment, the WN film (barrier metal layer 6c), which is an amorphous layer, is crystalized by the annealing, and changes into a W(N) layer (the barrier metal layer 6a), which is a crystalline layer. According to the present embodiment, the barrier metal layer 6a with a ratio k of less than 40% is formed from the barrier metal layer 6c with a ratio k of 40%, and the N concentration in the barrier metal layer 6a becomes lower than the N concentration in the barrier metal layer 6c. The barrier metal layer 6a after the annealing may include an N (nitrogen) concentration gradient. In FIG. 8B, the barrier metal layer 6c is annealed in a state that the barrier metal layer 6c is exposed to the concave portion Hb.

Next, the metal layer 25 is formed on a surface of the barrier metal layer 6a (FIG. 8C). The metal layer 25 is, for example, a W layer including W as a principal component, and is formed using WF₆ gas and B₂H₆ gas. The metal layer 25 of the present embodiment is formed as an amorphous layer at a temperature of, for example, 300° C. or below (preferably 20020 C. or below). The metal layer 25 of the present embodiment is formed as an initial film of the electrode material layer 6b. The N concentration in the barrier metal layer 6a of the present embodiment is higher than the N concentration in the metal layer 25.

Next, the metal layer 26 is formed on a surface of the metal layer 25 (FIG. 8C). The metal layer 26 is, for example, a W layer including W as a principal component, and is formed using WF₆ gas and H₂ gas. The metal layer 26 of the present embodiment is formed, for example, as a polycrystalline layer at a temperature of 450° C. According to the present embodiment, the metal layer 26 is formed at a temperature higher than is the metal layer 25. The metal layer 26 may be formed so as to include the seam Ga. The metal layer 26 is, for example, an LFW (low-fluorine tungsten) layer or a CVD-W (chemical-vapor-deposition tungsten) layer.

The metal layer 26 of the present embodiment forms the electrode material layer 6b in conjunction with the metal layer 25. The N concentration in the barrier metal layer 6a of the present embodiment is higher than the N concentration in the metal layer 26. The metal layer 26 is formed such that the N concentration will be, for example, 7.0×10¹⁹ to 2.0×20²⁰ atoms/cm³. Note that the N concentration is a value measured, for example, by SIMS (secondary ion mass spectrometry) analysis.

According to the present embodiment, the metal layer 25 may also be transformed from an amorphous layer to a polycrystalline layer during or after the formation of the metal layer 26. In that case, the metal layer 25 is crystalized by annealing at a temperature of, for example, 600° C. or above, and preferably 750° C. or above, and changes from an amorphous layer to a polycrystalline layer.

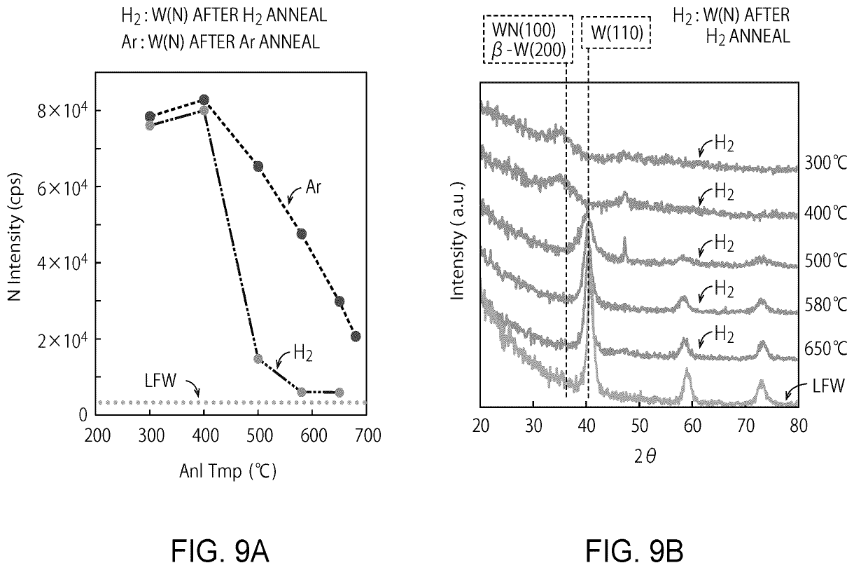

FIGS. 9A and 9B are graphs concerning characteristics of the semiconductor device of the first embodiment.

FIG. 9A shows results of XPS (X-ray photoelectron spectroscopy) analysis on the barrier metal layer 6a, where the abscissa represents annealing temperature of the barrier metal layer 6c and the ordinate represents intensity of N atoms (N intensity) in the barrier metal layer 6a. The N intensity decreases with decreases in the N concentration in the barrier metal layer 6a. FIG. 9A shows results of XPS analysis of the W(N) layer when annealing is performed using H₂ gas or Ar (argon) gas as the predetermined gas.

It can be seen from FIG. 9A that the N concentration in the barrier metal layer 6a becomes low when H₂ gas is used in the annealing and when Ar gas is used in the annealing. Moreover, it can be seen that the N concentration in the barrier metal layer 6a becomes lower when H₂ gas is used in the annealing. Thus, the barrier metal layer 6c of the present embodiment is preferably annealed using H₂ gas. It can also be seen from

FIG. 9A that when H₂ gas is used to anneal the W(N) layer, the N intensity of the W(N) layer starts to decrease at 400° C. and becomes far lower at 500° C. than at 400° C. Thus, the barrier metal layer 6c of the present embodiment is annealed at a temperature higher than 400° C., and desirably at a temperature of 500° C. or above.

In FIG. 9A, the barrier metal layer 6a annealed at 500° C. or above is higher in N intensity than an LFW layer (the metal layer 26). In this case, the N concentration in the barrier metal layer 6a is higher than N concentration in the LFW layer. The ratio k of the barrier metal layer 6a of the present embodiment is lower than 40% as described above, and desirably 10% or below. The ratio k of the barrier metal layer 6a of the present embodiment is, for example, 5% or below. As shown in FIG. 9A, annealing at 500° C. or above using H₂ gas can greatly reduce the N concentration in the barrier metal layer 6a, and thus the barrier metal layer 6a with the ratio k equal to or less than 10% or 5% can be realized by annealing at 500° C. or above using H₂ gas.

FIG. 9B shows results of X-ray scattering of the barrier metal layer 6a, where the abscissa represents scattering angle (2θ) and the ordinate represents scattering intensity. FIG. 9B shows results of X-ray scattering when the barrier metal layer 6c is annealed at 300° C., 400° C., 500° C., 580° C., or 650° C. using H₂ gas. FIG. 9B further shows results of X-ray scattering of the LFW layer (metal layer 26) as a comparative example.

It can be seen from FIG. 9B that a scattering peak of X-ray scattering is observed when the annealing temperature is 500° C. or above. From this it can be seen that the barrier metal layer 6a of the present embodiment is a crystalline layer, and tungsten included in the barrier metal layer 6a of the present embodiment includes a crystal structure having a (110) plane as a plane orientation. It can be seen from FIG. 9B that the LFW layer (metal layer 26) of the present embodiment is also a crystalline layer.

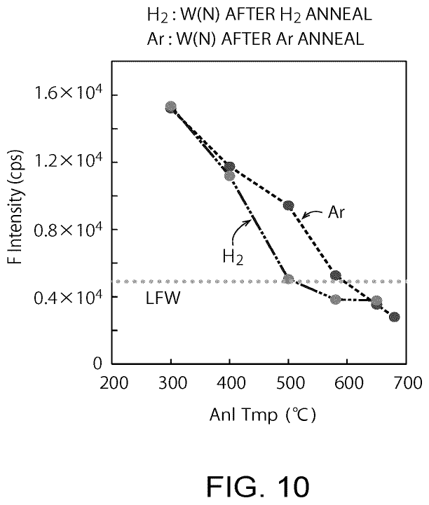

FIG. 10 is another graph concerning characteristics of the semiconductor device of the first embodiment.

FIG. 10 shows results of XPS analysis on the barrier metal layer 6a, where the abscissa represents annealing temperature of the barrier metal layer 6c and the ordinate represents intensity of F atoms (F intensity) in the barrier metal layer 6a. The F intensity decreases with decreases in the F concentration in the barrier metal layer 6a. FIG. 10 shows results of XPS analysis when annealing is performed using H₂ gas or Ar gas as the predetermined gas.

It can be seen from FIG. 10 that when annealing is performed using H₂ gas, if the annealing is done at 500° C., the F concentration in the barrier metal layer 6a can be decreased to a level almost equal to the F concentration in the LFW layer (metal layer 26). Thus, annealing at 500° C. or above is effective not only in reducing the N concentration in the barrier metal layer 6a, but also in reducing the F concentration in the barrier metal layer 6a.

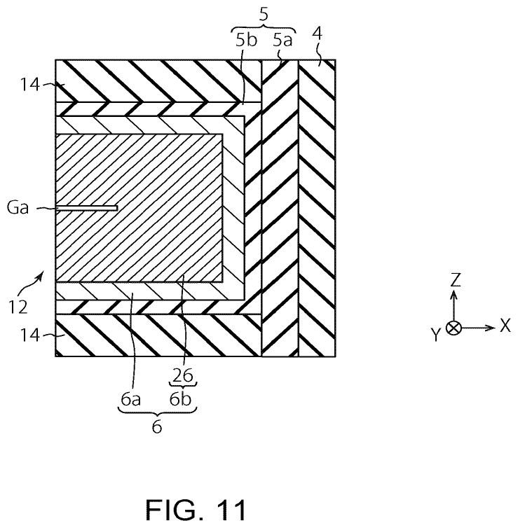

FIG. 11 is a sectional view showing a structure of a semiconductor device of a variation of the first embodiment.

The structure of the semiconductor device (FIG. 11) of the present variation is similar to the structure of the semiconductor device (FIG. 7) of the first embodiment. However, whereas the electrode material layer 6b of the first embodiment includes the metal layers 25 and 26, an electrode material layer 6b of the present variation includes only the metal layer 26. The semiconductor device of the present variation can be manufactured, for example, by a method shown in FIGS. 9A to 9B by omitting the step of forming the metal layer 25.

As described above, each of the electrode layers 6 of the first embodiment includes the barrier metal layer 6a which is a W(N) layer, and the electrode material layer 6b (the metal layers 25 and 26) which is a W layer. Thus, the present embodiment makes it possible to form the electrode layers 6 having suitable characteristics. For example, it becomes possible to reduce the electric resistance of the electrode layers 6 and inhibit diffusion of F atoms from the electrode layers 6 to other layers.

### Second Embodiment

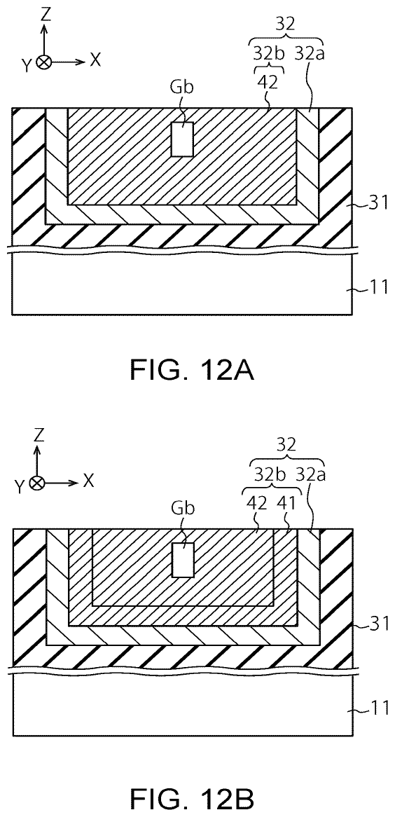

FIGS. 12A and 12B are sectional views showing a structure of a semiconductor device of a second embodiment, and a structure of a semiconductor device of a variation of the second embodiment.

FIG. 12A shows the semiconductor device of the second embodiment. The semiconductor device of the present embodiment includes an inter layer dielectric 31 formed on the substrate 11 described above, and an interconnect layer 32 formed in the inter layer dielectric 31. The interconnect layer 32 is, for example, one of a plurality of interconnect layers forming a multilayer interconnect structure of the semiconductor device of the present embodiment and includes one or more interconnects. FIG. 12A shows one of the interconnects. The interconnect layer 32 may be a plug layer that includes one or more contact plugs or one or more via plugs. The inter layer dielectric 31 is an example of the first insulator. The interconnect layer 32 is an example of the first interconnect layer.

The interconnect layer 32 shown in FIG. 12A includes a barrier metal layer 32a and an interconnect material layer 32b formed in sequence in the inter layer dielectric 31. The barrier metal layer 32a is formed on a side face and upper face of the inter layer dielectric 31. The interconnect material layer 32b includes a metal layer 42 formed on a side face and upper face of the barrier metal layer 32a. FIG. 12A further shows a seam Gb formed in the metal layer 42 when the metal layer 42 is formed. The seam Gb makes up an air gap extending generally in parallel to the Z direction. The barrier metal layer 32a is an example of the first layer. The metal layer 42 is an example of the second layer.

The barrier metal layer 32a of the present embodiment corresponds to the barrier metal layer 6a of the first embodiment and is formed by a method similar to the method for the barrier metal layer 6a of the first embodiment. Thus, the barrier metal layer 32a is, for example, a W(N) layer, and has an N concentration similar to the N concentration of the barrier metal layer 6a.

The metal layer 42 of the present embodiment corresponds to the metal layer 26 of the first embodiment and is formed by a method similar to the method for the metal layer 26 of the first embodiment. Thus, the metal layer 42 is, for example, a W layer, and has an N concentration similar to the N concentration of the metal layer 26.

Note that the interconnect layer 32 of the present embodiment does not include a metal layer corresponding to the metal layer 26 of the first embodiment. Thus, the interconnect layer 32 of the present embodiment has a structure similar to the structure of the electrode layer 6 of the variation of the first embodiment shown in FIG. 11.

FIG. 12B shows a semiconductor device of a variation of the second embodiment. A structure of the semiconductor device of the present variation is similar to the structure of the semiconductor device of the second embodiment shown in FIG. 12A. However, the interconnect material layer 32b of the present variation includes a metal layer 41 between the barrier metal layer 32a and the metal layer 42. The metal layer 41 is an example of the third layer.

The metal layer 41 of the present variation corresponds to the metal layer 25 of the first embodiment and is formed by a method similar to the method for the metal layer 25 of the first embodiment. Thus, the metal layer 41 is, for example, a W layer, and has an N concentration similar to the N concentration of the metal layer 25.

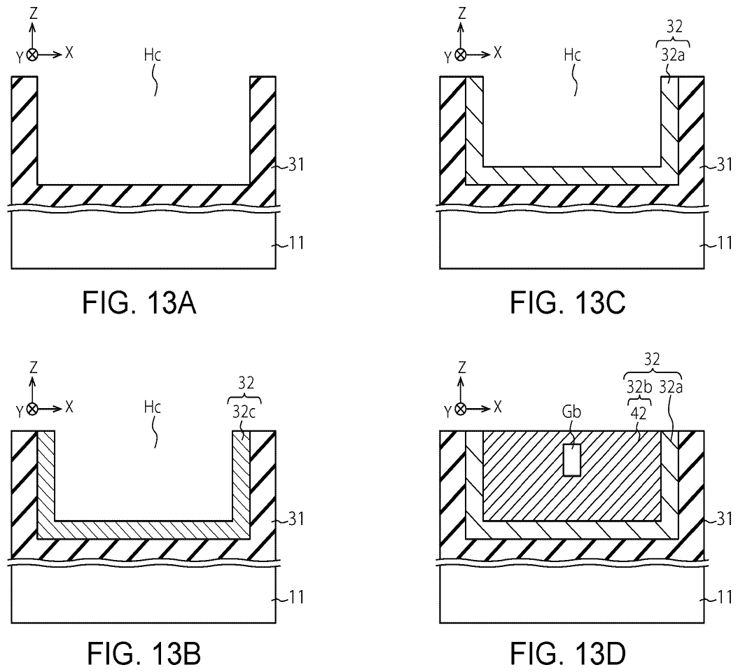

FIGS. 13A to 13D are sectional views showing a method of manufacturing the semiconductor device of the second embodiment.

First, the inter layer dielectric 31 is formed on the substrate 11, and an interconnect trench Hc is formed in the inter layer dielectric 31 by photolithography and RIE (FIG. 13A). The inter layer dielectric 31 may be formed on the substrate 11 either directly or via another layer. The interconnect trench Hc is an example of the first concave portion.

Next, a barrier metal layer 32c is formed on a side face and upper face of the inter layer dielectric 31 in the interconnect trench Hc (FIG. 13B). The barrier metal layer 32c is, for example, a WN film. The barrier metal layer 32c of the present embodiment is formed by CVD using WF₆ gas and NH₃ gas, and a composition ratio of W atoms and N atoms in the barrier metal layer 32c is 6:4. Consequently, the ratio k of the number n2of N atoms to the sum of the number of W atoms n1 and the number n2of N atoms in the barrier metal layer 32c is 40% (i.e., k32 n2/(n1+n2) =0.40). The barrier metal layer 32c is an example of the first layer. Note that illustration of the barrier metal layer 32c formed outside the interconnect trench Hc is omitted.

Next, the barrier metal layer 32c is annealed (FIG. 13C). The annealing is performed, for example, using a predetermined gas (e.g., H₂) at a temperature higher than 400° C. The annealing is performed at a temperature of, for example, 500° C. or above, but lower than 1050° C. As a result, the barrier metal layer 32c changes into the barrier metal layer 32a. The barrier metal layer 32a is, for example, a W(N) layer, i.e., a W layer including N atoms as impurity atoms. According to the present embodiment, the WN film (barrier metal layer 32c), which is an amorphous layer, is crystalized by the annealing, and changes into a W(N) layer (the barrier metal layer 32a), which is a crystalline layer. According to the present embodiment, the barrier metal layer 32a with a ratio k of less than 40% is formed from the barrier metal layer 32c with a ratio k of 40%, and the N concentration in the barrier metal layer 32a becomes lower than the N concentration in the barrier metal layer 32c.

Next, the metal layer 42 (interconnect material layer 32b) is formed on a side face and upper face of the barrier metal layer 32a in the interconnect trench Hc (FIG. 13C). The metal layer 42 is, for example, a W layer including W as a principal component, and is formed using WF₆gas and H₂ gas. The metal layer 42 of the present embodiment is formed, for example, as a polycrystalline layer at a temperature of 45020 C. The metal layer 42 may be formed so as to include the seam Gb. The metal layer 42 is, for example, an LFW layer or a CVD-W layer. The N concentration in the barrier metal layer 32a of the present embodiment is higher than the N concentration in the metal layer 42. The metal layer 42 is formed such that the N concentration will be, for example, 7.0×10¹⁹ to 2.0×20²⁰ atoms/cm³. Note that illustration of the metal layer 42 formed outside the interconnect trench Hc is omitted.

Subsequently, the barrier metal layer 32a and metal layer 42 formed outside the interconnect trench Hc are removed, for example, by CMP (chemical mechanical polishing). As a result, the interconnect layer 32 including the barrier metal layer 32a and metal layer 42 is formed.

In this way, the semiconductor device of the second embodiment shown in FIG. 12A is manufactured. Note that in manufacturing the semiconductor device of the variation of the second embodiment shown in FIG. 12B, the metal layer 41 is formed before the formation of the metal layer 42, but after the formation of the barrier metal layer 32a. The method of forming the metal layer 41 is similar to the method of forming the metal layer 25 in the step of FIG. 8C.

As described above, the interconnect layer 32 of the present embodiment includes the barrier metal layer 32a, which is a W(N) layer, and the interconnect material layer 32b, which is a W layer. Thus, the present embodiment makes it possible to form the interconnect layers 32 having suitable characteristics. For example, as with the electrode layers 6 of the first embodiment, it becomes possible to reduce the electric resistance of the interconnect layers 32 and inhibit diffusion of F atoms from the interconnect layers 32 to other layers.

### Third Embodiment

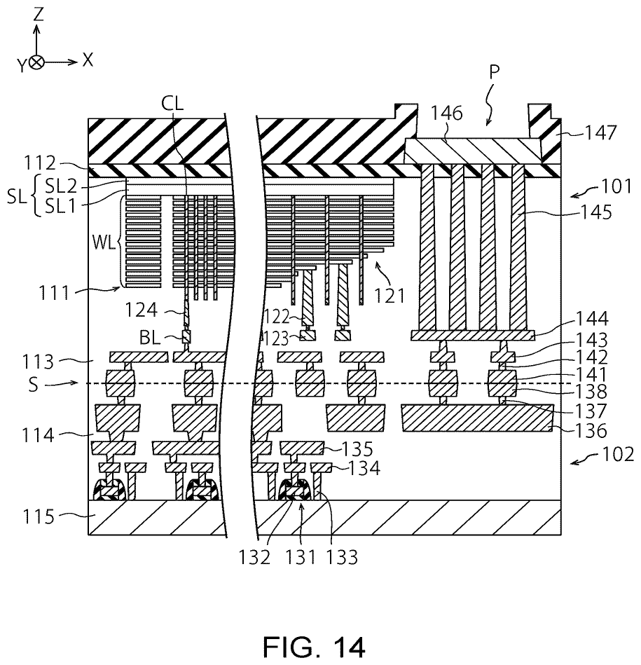

FIG. 14 is a sectional view showing a structure of a semiconductor device of a third embodiment. The semiconductor device of the present embodiment is, for example, a three-dimensional semiconductor memory, and is manufactured by laminating an array wafer including an array region 101 with a circuit wafer including a circuit region 102. Relationships between the present embodiment and the first and second embodiments will be described later.

The array region 101 includes a memory cell array 111 including a plurality of memory cells, an insulator 112 above the memory cell array 111, and an inter layer dielectric 113 under the memory cell array 111. The insulator 112 is, for example, a silicon oxide film or a silicon nitride film. The inter layer dielectric 113 is, for example, a silicon oxide film, or a stacked film including a silicon oxide film and another insulator.

The circuit region 102 is provided under the array region 101. FIG. 14 shows a boundary face (bonding face) S between the array region 101 and the circuit region 102. The circuit region 102 includes an inter layer dielectric 114 under the inter layer dielectric 113 and a substrate 115 under the inter layer dielectric 114. The inter layer dielectric 114 is, for example, a silicon oxide film, or a stacked film including a silicon oxide film and another insulator. The substrate 115 is a semiconductor substrate such as a silicon substrate.

FIG. 14 shows an X direction and a Y direction parallel to a surface of the substrate 115 and perpendicular to each other, and a Z direction perpendicular to the surface of the substrate 115. In the present specification, a +Z direction is treated as an upward direction and a −Z direction is treated as a downward direction. The −Z direction may or may not coincide with the gravity direction.

The array region 101 includes a plurality of word lines WL and a source line SL as a plurality of electrode layers in the memory cell array 111. FIG. 14 shows a staircase-like structure 121 of the memory cell array 111. Each of the word lines WL is electrically connected with a word line layer 123 via a contact plug 122. Each of columnar portions CL penetrating the plurality of word lines WL is electrically connected with a bit line BL via a via plug 124 and electrically connected with the source line SL. The source line SL includes a lower layer SL1, which is a semiconductor layer and an upper layer SL2, which is a metal layer.

The circuit region 102 includes a plurality of transistors 131. Each of the transistors 131 includes a gate electrode 132 provided on the substrate 115 via a gate insulator as well as a non-illustrated source diffusion layer and drain diffusion layer provided in the substrate 115. The circuit region 102 further includes the gate electrodes 132 of the transistors 131, a plurality of contact plugs 133 provided on the source diffusion layer or the drain diffusion layer, and interconnect layers 134 provided on the contact plugs 133 and including a plurality of interconnects.

The circuit region 102 includes an interconnect layer 135 provided above the interconnect layers 134 and including a plurality of interconnects; and an interconnect layer 136 provided above the interconnect layer 135 and including a plurality of interconnects. The circuit region 102 further includes a plurality of via plugs 137 provided on the interconnect layer 136 and a plurality of metal pads 138 provided on the via plugs 137. The metal pads 138 are, for example, metal layers including Cu (copper) layers. The circuit region 102 functions as a control circuit (logic circuit) adapted to control operation of the array region 101. The control circuit is made up of the transistors 131 and the like and electrically connected to the metal pads 138.

The array region 101 includes a plurality of metal pads 141 provided on the metal pads 138, and a plurality of via plugs 142 provided on the metal pads 141. The metal pads 141 are, for example, metal layers including Cu layers. The array region 101 further includes interconnect layers 143 provided on the via plugs 142 and including a plurality of interconnects; and an interconnect layer 144 provided on the interconnect layers 143 and including a plurality of interconnects. The bit line BL is included in the interconnect layer 144. The control circuit is electrically connected to the memory cell array 111 via the metal pads 141, 138, and the like, and controls operation of the memory cell array 111 via the metal pads 141, 138, and the like.

The array region 101 also includes a plurality of via plugs 145 provided on the interconnect layer 144, a metal pad 146 provided on the via plugs 145 and the insulator 112, and a passivation insulator 147 provided on the metal pad 146 and the insulator 112. The metal pad 146 is, for example, a metal layer including a Cu layer and functions as an external connection pad (bonding pad) of the semiconductor device of the present embodiment. The passivation insulator 147 is, for example, a stacked film including a silicon oxide film and a silicon nitride film and has an opening P that exposes an upper face of the metal pad 146. Through the opening P, the metal pad 146 can be electrically connected to a mounted substrate or another device via a bonding wire, a solder ball, a metal bump, or the like.

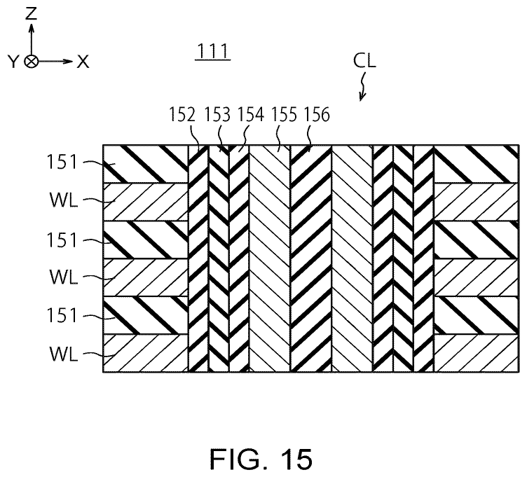

FIG. 15 is a sectional view showing a structure of a columnar portion CL of the third embodiment. FIG. 15 shows one of a plurality of columnar portions shown in FIG. 14.

As shown in FIG. 15, the memory cell array 111 includes the plurality of word lines WL and a plurality of insulators 151 stacked alternately on the inter layer dielectric 113 (see FIG. 14). The word lines WL are, for example, metal layers including W layers or the like. The insulators 151 are, for example, silicon oxide films.

The columnar portion CL includes a block insulator 152, a charge storage layer 153, a tunnel insulator 154, a channel semiconductor layer 155, and a core insulator 156 in sequence. The charge storage layer 153 is, for example, an insulator such as a silicon nitride film, and is formed on side faces of the word lines WL and insulators 151 via the block insulator 152. The channel semiconductor layer 155 is, for example, a polysilicon layer, and is formed on a side face of the charge storage layer 153 via the tunnel insulator 154. The block insulator 152, the tunnel insulator 154, and the core insulator 156 are, for example, silicon oxide films.

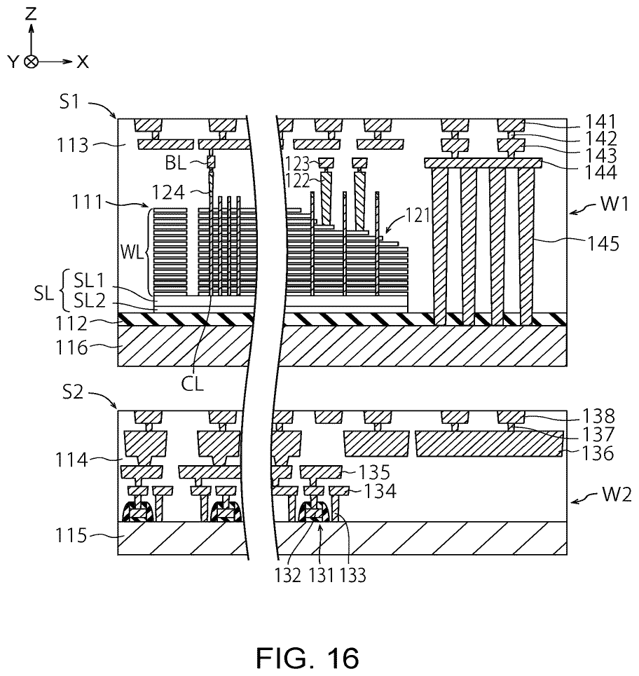

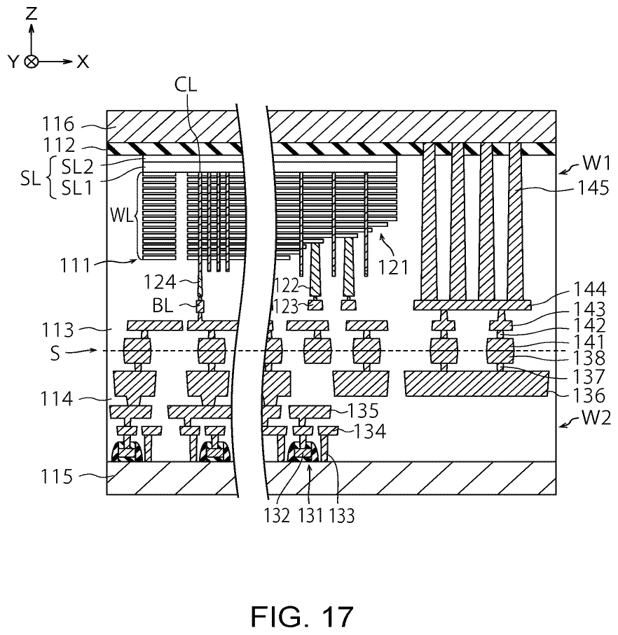

FIGS. 16 and 17 are sectional views showing a method of manufacturing the semiconductor device of the third embodiment.

FIG. 16 shows an array wafer W1 and a circuit wafer W2. Specifically, FIG. 16 shows one of a plurality of the array regions 101 included in the array wafer W1 and one of a plurality of the circuit regions 102 included in the circuit wafer W2.

The array wafer W1 in FIG. 16 is opposite in direction to the array region 101 in FIG. 14. According to the present embodiment, a plurality of the semiconductor devices are manufactured by bonding together the array wafer W1 and the circuit wafer W2. FIG. 16 shows the array wafer W1 before being reversed in direction for bonding and FIG. 14 shows the array region 101 after being bonded and diced by being reversed in direction for bonding.

FIG. 16 further shows an upper face S1 of the array wafer W1 and an upper face S2 of the circuit wafer W2. The array wafer W1 includes a substrate 116 provided under the insulator 112. The substrate 116 is a semiconductor substrate such as a silicon substrate.

According to the present embodiment, first, as shown in FIG. 16, the memory cell array 111, the insulator 112, the inter layer dielectric 113, the staircase-like structure 121, the metal pads 141, and the like are formed on the substrate 116 of the array wafer W1, and the inter layer dielectric 114, the transistors 131, the metal pads 138, and the like are formed on the substrate 115 of the circuit wafer W2. For example, the via plugs 145, the interconnect layer 144, the interconnect layers 143, the via plugs 142, and the metal pads 141 are formed in sequence on the substrate 116. The contact plugs 133, the interconnect layers 134, the interconnect layer 135, the interconnect layer 136, the via plugs 137, and the metal pads 138 are formed on the substrate 115. Next, as shown in FIG. 17, the array wafer W1 and the circuit wafer W2 are bonded together by mechanical pressure. Consequently, the inter layer dielectric 113 and the inter layer dielectric 114 are bonded together. Next, the array wafer W1 and the circuit wafer W2 are annealed. Consequently, the metal pads 141 and the metal pads 138 are joined together.

Subsequently, the substrate 115 is reduced in thickness by CMP and the substrate 116 is removed by CMP, and then the array wafer W1 and the circuit wafer W2 are diced into a plurality of chips. In this way, the semiconductor device shown in FIG. 14 is manufactured. Note that the metal pad 146 and the passivation insulator 147 are formed on the insulator 112, for example, after the substrate 115 is reduced in thickness and the substrate 116 is removed.

Note that whereas FIG. 14 shows a boundary face between the inter layer dielectric 113 and the inter layer dielectric 114 as well as a boundary face between the metal pads 141 and the metal pads 138, it is generally the case that the boundary faces can no longer be observable after the annealing. However, locations where the boundary faces existed can be estimated by detecting, for example, inclinations of side faces of the metal pads 141 and inclinations of side faces of the metal pads 138, and displacement between the side faces of the metal pads 141 and the side faces of the metal pads 138.

Next, relationships between the present embodiment and the first and second embodiments will be described.

The word lines WL of the present embodiment may be formed, for example, by a method similar to the method for the electrode layers 6 of the first embodiment. This makes it possible to reduce the electric resistance of the word lines WL and inhibit diffusion of F atoms from the word lines WL to other layers. In this case, the substrate 116, insulators 151, block insulator 152, charge storage layer 153, tunnel insulator 154, channel semiconductor layer 155, and core insulator 156 of the present embodiment correspond respectively to the substrate 11, insulator 14, block insulator 5, charge storage layer 4, tunnel insulator 3, channel semiconductor layer 2, and core insulator 1 of the first embodiment. However, the substrate 116 of the present embodiment is removed after the array wafer W1 and the circuit wafer W2 are bonded together, does not remain in the manufactured semiconductor device.

At least any of the interconnect layers 134, 135, 136, 143, and 144 of the present embodiment may be formed, for example, by a method similar to the method for the interconnect layer 32 of the second embodiment. This will make it possible to reduce electric resistance of the interconnect layer(s) and inhibit diffusion of F atoms from the interconnect layer(s) to other layers. In this case, the substrate 116 or substrate 115 of the present embodiment corresponds to the substrate 11 of the second embodiment while the inter layer dielectric 114 or inter layer dielectric 113 corresponds to the inter layer dielectric 31 of the second embodiment. However, the substrate 116 of the present embodiment is removed after the array wafer W1 and the circuit wafer W2 are bonded together, and thus does not remain in the manufactured semiconductor device.

Thus, as with the first and second embodiments, the present embodiment makes it possible to form interconnect layers having suitable characteristics.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming a first insulator;
forming a first layer including tungsten and nitrogen, on the first insulator;
reducing nitrogen concentration in the first layer by annealing the first layer in a state that the first layer is exposed; and
forming a second layer including tungsten, on the first layer after the annealing.

2. The method of claim 1, wherein the annealing is performed at a temperature higher than 400° C. and lower than 1050° C.

3. The method of claim 1, wherein the annealing is performed using H₂ (hydrogen) gas.

4. The method of claim 1, wherein the annealing is performed using Ar (argon) gas or N₂ (nitrogen) gas.

5. The method of claim 1, wherein the first layer before the annealing is a WN film (tungsten nitride film).

6. The method of claim 1, wherein the first layer is formed by CVD (chemical vapor deposition).

7. The method of claim 1, wherein the first layer is crystalized by the annealing.

8. The method of claim 1, wherein tungsten included in the first layer after the annealing includes a crystal structure having a (110) plane.

9. The method of claim 1, wherein the first layer and the second layer are formed such that nitrogen concentration in the first layer after the annealing is higher than nitrogen concentration in the second layer, and that a ratio of a number of nitrogen atoms to a sum of a number of tungsten atoms and the number of nitrogen atoms in the first layer after the annealing is lower than 40%.

10. The method of claim 1, further comprising:
forming a stacked film alternately including a plurality of fourth layers and a plurality of second insulators;
forming a charge storage layer on side faces of the plurality of fourth layers via a third insulator; and
forming a semiconductor layer on a side face of the charge storage layer via a fourth insulator,
removing the plurality of fourth layers to form a plurality of first concave portions in the stacked film; and
forming a plurality of electrode layers in the plurality of first concave portions,
wherein the first layer and the second layer are one electrode layer of the plurality of electrode layers.

11. A semiconductor device comprising:
a first insulator; and
a first interconnect layer including a first layer that is provided on the first insulator and includes tungsten and nitrogen, and a second layer
wherein
nitrogen concentration in the first layer is higher than nitrogen
tungsten included in the first layer includes a crystal structure having a (110) plane.

12. The device of claim 11, wherein the first layer includes tungsten as a principal component, and includes nitrogen atoms as impurity atoms.

13. The device of claim 11, wherein a ratio of a number of nitrogen atoms to a sum of a number of tungsten atoms and the number of nitrogen atoms in the first layer is lower than 40%.

14. The device of claim 11, wherein the nitrogen concentration in the second layer is 7.0×10¹⁹ to 2.0×20²⁰ atoms/cm³.

15. The device of claim 11, wherein the second layer further includes fluorine or chlorine.

16. The device of claim 11, wherein the first layer is a barrier metal layer, and the second layer is an interconnect material layer.

17. The device of claim 11, wherein the first interconnect layer further includes a third layer that is provided between the first layer and the second layer and includes tungsten.

18. The device of claim 17, wherein the third layer further includes boron or silicon.

19. A semiconductor device comprising:
a stacked film alternately including a plurality of electrode layers and a plurality of second insulators;
a charge storage layer provided on side faces of the plurality of electrode layers via a third insulator; and
a semiconductor layer provided on a side face of the charge storage layer via a fourth insulator.
wherein
an electrode layer of the plurality of electrode layers includes a first layer that includes tungsten and nitrogen, and a second layer that is provided on the first layer and includes tungsten,
nitrogen concentration in the first layer is higher than nitrogen concentration in the second layer, and tungsten included in the first layer includes a crystal structure having a (110) plane.

20. The device of claim 19, wherein the electrode layer of the plurality of electrode layers further includes a third layer that is provided between the first layer and the second layer and includes tungsten.
